(19) United States
(12) Patent Application Publication
(10) Pub. No.: US 2016/0099306 A1
(43) Pub. Date: Apr. 7, 2016

(54) MONOLITHIC MERGED PIN SCHOTTKY DIODE STRUCTURE

(71) Applicant: Beyond Innovation Technology Co., Ltd., Taipei City (TW)

(72) Inventor: Chien-Hsing Cheng, Taipei City (TW)

(21) Appl. No.: 14/730,246

(22) Filed: Jun. 4, 2015

(30) Foreign Application Priority Data
Oct. 1, 2014 (TW) 103134214

(51) Int. Cl. H01L 29/06; H01L 29/868; H01L 27/07; H01L 29/872

(52) U.S. Cl. CPC H01L 29/0619; H01L 29/872; H01L 29/8725; H01L 29/868; H01L 27/0788

(57) ABSTRACT

A monolithic merged PIN Schottky (MPS) diode including a chip, at least one PIN diode, at least one Schottky diode and a termination structure is provided. The chip has a first active area, a second active area and a termination area. The PIN diode is disposed in the first active area. The Schottky diode is disposed in the second active area. The termination structure is disposed in the termination area. The first active area and the second active area are separated by the termination area. The PIN diode and the Schottky diode share the termination structure.

### CROSS-REFERENCE TO RELATED APPLICATION

This application claims the priority benefit of Taiwan application serial no. 103134214, filed on Oct. 1, 2014. The entirety of the above-mentioned patent application is hereby incorporated by reference herein and made a part of this specification.

### BACKGROUND OF THE INVENTION

1. Field of the Invention

The invention relates to a semiconductor structure, and particularly relates to a monolithic merged PIN Schottky (MPS) diode structure.

2. Description of Related Art

A power diode is one of the key components in a circuit system, and is broadly applied in business and military products such as high-frequency inverters, digital products, power generators, TVs, etc.

The most commonly used power diodes are PIN diodes and Schottky diodes. PIN diodes have a high breakdown voltage and a low reverse current, but the turn-on/off speed thereof is slow. The Schottky diodes have a high turn-on/off speed, a low turn-on voltage drop, and a high forward turn-on current. However, the characteristics relating to leakage currents of the Schottky diodes are less desirable. Thus, how to effectively integrate a PIN diode and a Schottky diode to improve the turn-on/off characteristics is an important issue to be worked on.

### SUMMARY OF THE INVENTION

Accordingly, the invention provides a monolithic merged PIN Schottky (MPS) diode structure capable of reducing a device size and improving a device performance.

The invention provides a monolithic merged PIN Schottky diode, including a chip, at least one PIN diode, at least one Schottky diode, and a termination structure. The chip has a first active area, a second active area, and a termination area. The PIN diode is disposed in the first active area. The Schottky diode is disposed in the second active area. The termination structure is disposed in the termination area. In addition, the termination area separates the first active area and the second active area, and the PIN diode and the Schottky diode share the termination structure.

According to an embodiment of the invention, the termination structure surrounds the PIN diode and the Schottky diode.

According to an embodiment of the invention, the PIN diode includes a planar-type PIN diode or a trench-type PIN diode.

According to an embodiment of the invention, the Schottky diode includes a planar-type Schottky diode or a trench-type Schottky diode.

According to an embodiment of the invention, the Schottky diode includes a junction barrier Schottky (JBS) diode or a trench MOS barrier Schottky (TMBS) diode.

According to an embodiment of the invention, the termination structure includes a field plate structure, a field plate structure with a floating guard ring, a floating trench structure, a guard ring structure, a floating limitation ring structure, or a structure having a floating trench and a wider trench outer.

According to an embodiment of the invention, a substrate of the chip includes a silicon substrate, a silicon-on-insulator (SOI) substrate, or a Group III-V semiconductor substrate.

According to an embodiment of the invention, an area of the first active area is substantially equal to an area of the second active area.

According to an embodiment of the invention, an area of the first active area is bigger than an area of the second active area.

According to an embodiment of the invention, an area of the first active area is smaller than an area of the second active area.

Based on the above, a PIN diode and a Schottky diode are integrated into a single chip in the invention, and the PIN diode and the Schottky diode share a termination structure. Thus, the device size may be reduced, and the improved turn-on/off characteristics can be achieved.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view illustrating a monolithic merged PIN Schottky diode according to an embodiment of the invention.

FIG. 2 is a cross-sectional schematic view taken along the A-A line in FIG. 1.

FIG. 3 is another cross-sectional schematic view taken along the A-A line in FIG. 1.

FIG. 4 is a cross-sectional schematic view illustrating a termination structure according to an embodiment of the invention.

FIG. 5 is a cross-sectional schematic view illustrating a termination structure according to another embodiment of the invention.

FIG. 6 is a schematic top view illustrating a monolithic merged PIN Schottky diode according to another embodiment of the invention.

FIG. 7 is a schematic top view illustrating a monolithic merged PIN Schottky diode according to yet another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In a monolithic merged PIN Schottky diode structure according to the invention, a PIN diode and a Schottky diode are integrated into a chip, and the PIN diode and the Schottky diode share a termination structure.

The invention does not intend to limit the type of a PIN diode. The PIN diode may include a planar-type PIN diode or a trench-type PIN diode, or the like.

Also, the invention does not intend to limit the type of a Schottky diode. The Schottky diode may include a planar-type Schottky diode or a trench-type Schottky diode, etc., such as a junction barrier Schottky (JBS) diode or a trench MOS barrier Schottky (TMBS) diode, or the like.

Moreover, the invention does not limit the type of a termination structure. The termination structure may include a field plate structure, a field plate structure with a floating guard ring, a floating trench structure, a guard ring structure, a floating limitation ring structure, or a structure having a floating trench and a wider trench outer, or the like.

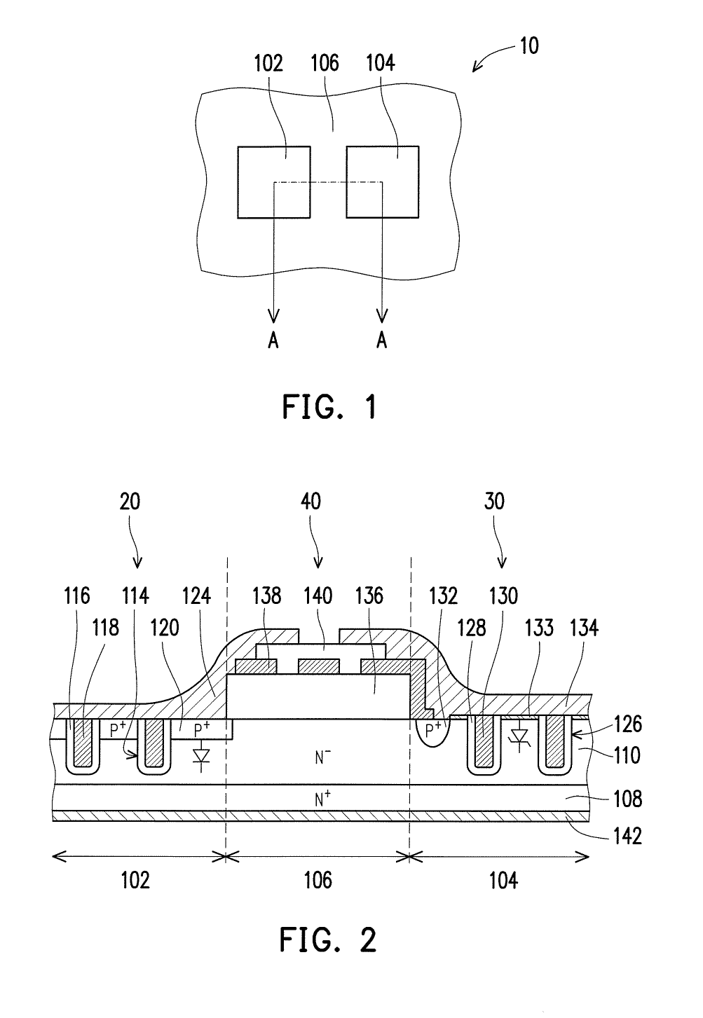

FIG. 1 is a schematic top view illustrating a monolithic merged PIN Schottky diode according to an embodiment of the invention. FIG. 2 is a cross-sectional schematic view taken along the A-A line in FIG. 1.

Referring to FIG. 1 and FIG. 2, the monolithic merged PIN Schottky diode includes a chip 10, a PIN diode 20, a Schottky diode 30, and a termination structure 40. The chip 10 has a first active area 102, a second active area 104, and a termination area 106. In addition, the termination area 106 separates the first active area 102 and the second active area 104. In an embodiment, the termination area 106 surrounds the first active area 102 and the second active area 104.

As shown in FIG. 2, the PIN diode 20 is disposed in the first active area 102. The Schottky diode 30 is disposed in the second active area 104. The termination structure 40 is disposed in the termination area 106. In this embodiment, the PIN diode 20 is a trench-type PIN diode, the Schottky diode 30 is a TMBS diode, and the termination structure 40 is a field plate structure. However, the invention is not limited thereto.

In the first active area 102, an N⁻ epitaxial layer 110 is disposed on an N⁺ substrate 108. The N⁺ substrate includes a silicon substrate, a silicon-on-insulator (SOI) substrate, and a Group III-V semiconductor substrate. The Group III-V semiconductor substrate may be a SiC substrate, a GaAs substrate, or a GaN substrate. A plurality of trenches 114 is disposed in the N⁻ epitaxial layer 110. An insulating layer 116 is disposed on a surface of each trench 114. The insulating layer 116 includes silicon oxide. A conductive layer 118 is filled into each trench 114. The conductive layer 118 includes polysilicon. A plurality of P⁺ doped regions 120 is disposed in the N⁻ epitaxial layer 110 between the trenches 114. In an embodiment, one P⁺ doped region 120 is disposed in the N⁻ epitaxial layer 110 at a side closely adjacent to the termination area 106; that is, the P⁺ doped region 120 is located in the N⁻ epitaxial layer 110 between the trench 114 closest to the termination area 106 and the termination area 106. A conductive layer 124 is disposed on the N⁻ epitaxial layer 110. A conductive layer 142 is disposed on another surface of the N⁺ substrate 108 opposite to the N⁻ epitaxial layer 110. Each of the conductive layer 124 and the conductive layer 142 includes metal, such as aluminum, copper, or an alloy thereof. In this embodiment, the N⁻ epitaxial layer 110 and the P⁺ doped region 120 constitute a PIN diode 20.

In the second active area 104, the N⁻ epitaxial layer 110 is disposed on the N⁺ substrate 108. A plurality of trenches 126 is disposed in the N⁻ epitaxial layer 110. An insulating layer 128 is disposed on a surface of each trench 126. The insulating layer 128 includes silicon oxide. A conductive layer 130 is filled into each trench 126. The conductive layer 130 includes polysilicon. A P⁺ doped region 132 is disposed in the N⁻ epitaxial layer 110 at another side closely adjacent to the termination area 106. In an embodiment, the P⁺ doped region 132 is disposed in the N⁻ epitaxial layer 110 between the trench 126 closest to the termination area 106 and the termination area 106, but the P⁺ doped region 132 does not contact the trench 126. A Schottky barrier metal layer 133 is disposed on the N⁻ epitaxial layer 110 between the adjacent trenches 126 and between the trench 126 and the P⁺ doped region 132. The Schottky metal layer 133 includes Ti, TiNi, NiCr, NiV, or Pt. A conductive layer 134 is disposed on the N⁻ epitaxial layer 110. The conductive layer 142 is disposed on another surface of the N⁺ substrate 108 opposite to the N⁻ epitaxial layer 110. Each of the conductive layer 134 and the conductive layer 142 includes metal, such as aluminum, copper, or an alloy thereof. In this embodiment, the N⁻ epitaxial layer 110 and the Schottky barrier metal layer 133 constitute a Schottky diode 30.

In the termination structure 40 of the termination area 106, the N⁻ epitaxial layer 110 is disposed on the N⁺ substrate 108. A field oxide layer 136 is disposed on the N⁻ epitaxial layer 110. The field oxide layer 136 includes silicon oxide. A plurality of conductive layers 138 is disposed on the field oxide layer 136. In an embodiment, one conductive layer 138 further extends to cover a side surface of the field oxide layer 136 and is electrically connected to the P⁺ doped region 132. The conductive layer 138 includes polysilicon. A dielectric layer 140 is filled into gaps between the conductive layers 138 and partially exposes the surfaces of the conductive layers 138 at external sides. Besides, the conductive layers 124 and 134 further extend onto a portion of the field oxide layer 136 and are electrically connected to the conductive layers 138 at the external sides.

In this embodiment, the trenches 114 and 126 may be completed in the same patterning process, the insulating layers 116 and 128 may be completed in the same patterning process, the conductive layers 118, 130, and 138 may be completed in the same patterning process, and the conductive layers 124 and 134 may be completed in the same patterning process. Also, the conductive layers 124 and 134 may serve as anode, while the conductive layer 142 may serve as cathode.

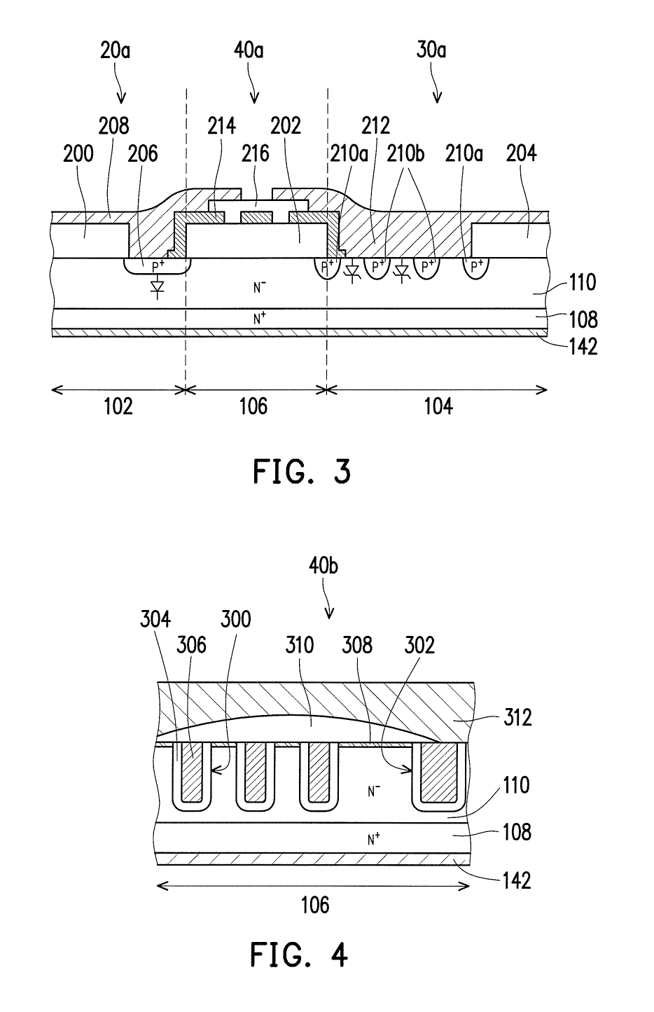

In the above embodiment, the PIN diode and the Schottky diode are both exemplified as trench-type diodes. However, the invention is not limited thereto. In another embodiment, the PIN diode and the Schottky diode may both be planar-type diodes, as shown in FIG. 3.

Referring to FIG. 1 and FIG. 3, the monolithic merged PIN Schottky diode includes the chip 10, a PIN diode 20a, a Schottky diode 30a, and a termination structure 40a. In this embodiment, the PIN diode 20a is a planar-type PIN diode, the Schottky diode 30a is a JBS diode, and the termination structure 40a is a field plate structure. However, the invention is not limited thereto.

In the first active area 102, the N⁻ epitaxial layer 110 is disposed on the N⁺ substrate 108. A field oxide layer 200 is disposed on the N⁻ epitaxial layer 110. The field oxide layer 200 includes silicon oxide. One P⁺ doped region 206 is disposed in the N⁻ epitaxial layer 110 at a side closely adjacent to the termination area 106; that is, the P⁺ doped region 206 is located in the N⁻ epitaxial layer 110 between the field oxide layer 200 and the termination area 106. A conductive layer 208 is disposed on the N⁻ epitaxial layer 110, covers the field oxide layer 200, and is electrically connected to the P⁺ doped region 206. The conductive layer 142 is disposed on another surface of the N⁺ substrate 108 opposite to the N⁻ epitaxial layer 110. Each of the conductive layer 208 and the conductive layer 142 includes metal, such as aluminum, copper, or an alloy thereof. In this embodiment, the N⁻ epitaxial layer 110 and the P⁺ doped region 206 constitute a PIN diode 20a.

In the second active area 104, the N⁻ epitaxial layer 110 is disposed on the N⁺ substrate 108. A field oxide layer 204 is disposed on the N⁻ epitaxial layer 110. The field oxide layer 204 includes silicon oxide. A plurality of P⁺ doped regions 210a is disposed in the N⁻ epitaxial layer 110 between the field oxide layer 204 and the termination area 106. A plurality of P⁺ doped regions 210b is optionally disposed in the N⁻ epitaxial layer 110 between the P⁺ doped regions 210a. A conductive layer 212 is disposed on the N″ epitaxial layer 110, covers the field oxide layer 204, and is electrically connected to the P⁺ doped regions 210a and 210b. The conductive layer 142 is disposed on another surface of the N⁺ substrate 108 opposite to the N⁻ epitaxial layer 110. Each of the conductive layer 212 and the conductive layer 142 includes metal, such as aluminum, copper, or an alloy thereof. In this embodiment, the N″ epitaxial layer 110 and the conductive layer 212 constitute Schottky diodes 30a. More specifically, the conductive layer 212 and the N⁻ epitaxial layer 110 between the P⁺ doped regions 210a and 210b constitute a Schottky diode 30a, and the conductive layer 212 and the N⁻ epitaxial layer 110 between the adjacent P⁺ doped regions 210b constitute another Schottky diode 30a.

In another embodiment (not shown), the step of forming the P⁺ doped region 210b may be omitted. Accordingly, only the Schottky diode formed by the conductive layer 212 and the N⁻ epitaxial layer 110 between the adjacent P⁺ doped regions 210a is provided in the second active area 104.

In the termination structure 40a of the termination area 106, the N⁻ epitaxial layer 110 is disposed on the N⁺ substrate 108. A field oxide layer 202 is disposed on the N⁻ epitaxial layer 110. The field oxide layer 202 includes silicon oxide. A plurality of conductive layers 214 is disposed on the field oxide layer 136. In an embodiment, the conductive layers 214 at the external sides further extend to cover side surfaces of the field oxide layer 202 and are electrically connected to the P⁺ doped regions 206 and 210a. The conductive layer 214 includes polysilicon. A dielectric layer 216 is filled into gaps between the conductive layers 214 and partially exposes the surfaces of the conductive layer 214 at external sides. Besides, the conductive layers 208 and 212 further extend onto a portion of the field oxide layer 202 and are electrically connected to the conductive layers 214 at the external sides.

In this embodiment, the field oxide layers 200, 202, and 204 may be completed in the same patterning process, the P⁺ doped regions 206, 210a, and 210b may be completed in the same patterning process, and the conductive layers 208 and 212 may be completed in the same patterning process. Also, the conductive layers 208 and 212 may serve as anode, while the conductive layer 142 may serve as cathode.

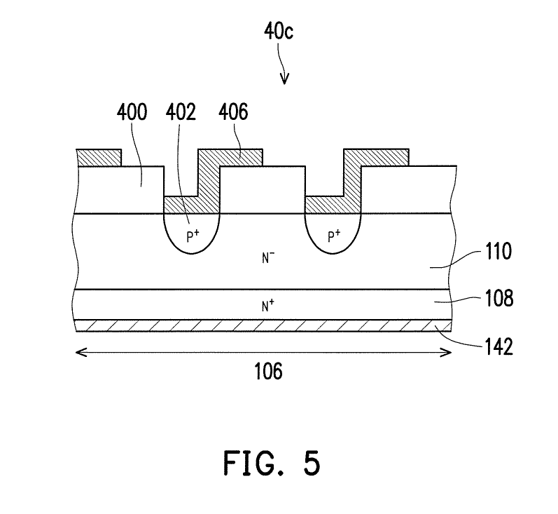

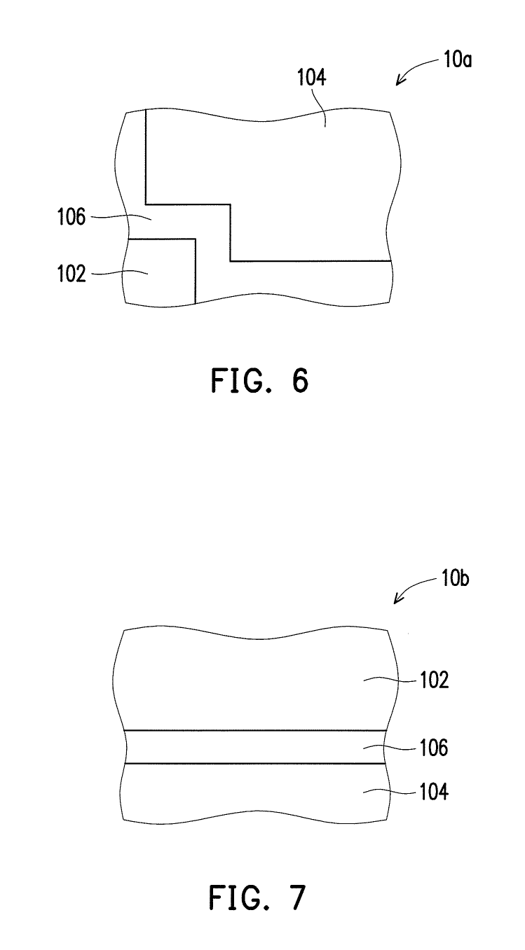

In the embodiments shown in FIG. 2 and FIG. 3, the termination structures are both field plate structures. However, the invention is not limited thereto. For example, the termination structure may be a structure having a floating trench and a wider trench outer (as shown in FIG. 4) or a guard ring structure (as shown in FIG. 5).

Referring to FIG. 4, in the termination area 106, the N⁻ epitaxial layer 110 is disposed on the N⁺ substrate 108. A plurality of narrow trenches 300 and a wide trench 302 are disposed in the N⁻ epitaxial layer 110, and the wider trench 302 is located at an outer side with respect to the narrow trench 300. An insulating layer 304 is disposed on a surface of each of the narrow trenches 300 and the wide trench 302. A conductive layer 306 is filled into each of the narrow and wide trenches 300 and 302. A Schottky barrier metal layer 308 is disposed on the N⁻ epitaxial layer 110 between the adjacent narrow trenches 300 and between the narrow trench 300 and the wide trench 302. The Schottky barrier metal layer 308 includes Ti, TiNi, NiCr, NiV, or Pt. A dielectric layer 310 is disposed on the N⁻ epitaxial layer 110, covers the narrow trenches 300, and exposes a portion of the conductive layer 306 in the wide trench 302. The dielectric layer 310 includes silicon oxide. A conductive layer 312 is disposed on the N⁻ epitaxial layer 110 and electrically connected to the conductive layer 306 in the wide trench 302. The conductive layer 142 is disposed on another surface of the N⁺ substrate 108 opposite to the N⁻ epitaxial layer 110. Each of the conductive layer 312 and the conductive layer 142 includes metal, such as aluminum, copper, or an alloy thereof.

Referring to FIG. 5, in the termination area 106, the N⁻ epitaxial layer 110 is disposed on the N⁺ substrate 108. A plurality of field oxide layers 400 is disposed on the N⁻ epitaxial layer 110. The field oxide layers 400 include silicon oxide. A plurality of P⁺ doped regions 402 is disposed in the N⁻ epitaxial layer 110 between the field oxide layers 400. Conductive layers 406 respectively cover portions of top surfaces and side surfaces of the field oxide layers 400, and are electrically connected to the P⁺ doped regions 402. The conductive layer 142 is disposed on another surface of the N⁺ substrate 108 opposite to the N⁻ epitaxial layer 110. Each of the conductive layer 406 and the conductive layer 142 includes metal, such as aluminum, copper, or an alloy thereof.

In the above embodiments, an area of the first active area 102 is substantially equal to an area of the second active area 104, as shown in FIG. 1. However, the invention is not limited thereto. It is not departed from the spirit of the invention as long as the PIN diode and the Schottky diode are integrated into a single chip. Thus, the areas of the first active area and the second active area may be adjusted based on the practical requirements, such that the overall design can be more flexible. In an embodiment, the area of the first active area 102 may be designed to be smaller than the area of the second active area 104, and the second active area 104 is in an irregular shape. In another embodiment, the area of the first active area 102 may be designed to be bigger than the area of the second active area 104, and the first and second active areas 102 and 104 are in stripe shapes, as shown in FIG. 7.

Besides, in the invention, the PIN diode 20/20a in the first active area 102, the Schottky diode 30/30a in the second active area 104, and the termination structure 40/40a/40b/40c in the termination area 106 may be arbitrarily arranged and/or combined. The said arrangements of the PIN diode, the Schottky diode, and the termination structure are provided for illustration purposes, and are not construed as limiting the present invention. More specifically, the monolithic merged PIN Schottky diode structure is contemplated as falling within the spirit and scope of the present invention as long as the structure includes a PIN diode and a Schottky diode which are integrated into a chip and share a termination structure. Thus, it is not necessary to limit the types of PIN diode, the Schottky diode, and the termination structure. The monolithic merged PIN Schottky diode structure according to the invention can be any combination of the PIN diode, the Schottky diode, and the termination structure.

In view of the foregoing, at least one PIN diode and at least one Schottky diode are integrated into a single chip in the invention, and the PIN diode and the Schottky diode share a termination structure. Thus, the device size may be reduced. Besides, by integrating the PIN diode and the Schottky diode, the improved switching characteristics can be achieved. In other words, the monolithic merged PIN Schottky diode structure is provided with a high breakdown voltage, a low reverse current, and a high turn-on/off speed, and is thus a competitive product. Besides, the respective areas of the PIN diode and the Schottky diode may be adjusted based on the practical requirements. Thus, the overall design is more flexible.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A monolithic merged PIN Schottky diode, comprising:
a chip, having a first active area, a second active area, and a termination area;
at least one PIN diode, disposed in the first active area;
at least one Schottky diode, disposed in the second active area; and
a termination structure, disposed in the termination area, wherein the termination area separates the first active area and the second active area, and the PIN diode and the Schottky diode share the termination structure.

2. The monolithic merged PIN Schottky diode as claimed in claim 1, wherein the termination structure surrounds the PIN diode and the Schottky diode.

3. The monolithic merged PIN Schottky diode as claimed in claim 1, wherein the PIN diode comprises a planar-type PIN diode or a trench-type PIN diode.

4. The monolithic merged PIN Schottky diode as claimed in claim 1, wherein the Schottky diode comprises a planar-type Schottky diode or a trench-type Schottky diode.

5. The monolithic merged PIN Schottky diode as claimed in claim 1, wherein the Schottky diode comprises a junction barrier Schottky (JBS) diode or a trench MOS barrier Schottky (TMBS) diode.

6. The monolithic merged PIN Schottky diode as claimed in claim 1, wherein the termination structure comprises a field plate structure, a field plate structure with a floating guard ring, a floating trench structure, a guard ring structure, a floating limitation ring structure, or a structure having a floating trench and a wider trench outer.

7. The monolithic merged PIN Schottky diode as claimed in claim 1, wherein a substrate of the chip comprises a silicon substrate, a silicon-on-insulator (SOI) substrate, or a Group III-V semiconductor substrate.

8. The monolithic merged PIN Schottky diode as claimed in claim 1, wherein an area of the first active area is substantially equal to an area of the second active area.

9. The monolithic merged PIN Schottky diode as claimed in claim 1, wherein an area of the first active area is bigger than an area of the second active area.

10. The monolithic merged PIN Schottky diode as claimed in claim 1, wherein an area of the first active area is smaller than an area of the second active area.
